(19) United States
(12) Patent Application Publication
(10) Pub. No.: US 2017/0063323 A1
(43) Pub. Date: Mar. 2, 2017

(54) Circuit Board, Housing of Electrical Component and Filter

(71) Applicant: FEEI CHERNG ENTERPRISE CO., LTD., New Taipei City (TW)

(72) Inventor: Shu-Mei Yang, New Taipei City (TW)

(21) Appl. No.: 14/967,486

(22) Filed: Dec. 14, 2015

(30) Foreign Application Priority Data
Aug. 28, 2015 (TW) 104128535

(51) Int. Cl. H03H 7/01; H05K 1/11; H05K 7/14

(52) U.S. Cl. CPC H03H 7/0138; H05K 7/1417; H05K 1/111; H05K 2201/1003; H05K 2201/1006

(57) ABSTRACT

The present invention provides a circuit board, a housing including the aforementioned circuit board, and a filter including the aforementioned circuit board or housing. The circuit board includes an upper surface, a lower surface opposite to the upper surface, and at least one side surface connected between the upper and lower surfaces. The at least one side surface includes grooves formed therein and extending through the upper and lower surfaces. The circuit board further includes upper solder pads, lower solder pads, and conductive connections. The upper and lower solder pads are disposed flat against the upper and lower surfaces, respectively, and separately located beside the grooves. The conductive connections are separately disposed in the grooves and provide guide grooves within the grooves. Two ends of each of the conductive connections are separately connected to corresponding one of the upper solder pads and corresponding one of the lower solder pads.

### CROSS-REFERENCE TO RELATED APPLICATIONS

The present application is based on, and claims priority from, Taiwan application number 104214042, filed Aug. 28, 2015, the disclosure of which is hereby incorporated by reference herein in its entirety.

### BACKGROUND OF THE INVENTION

1. Field of the Invention

The present invention relates to a circuit board, a housing of an electrical component, and a filter.

2. Description of the Prior Art

The conventional filter includes a housing, terminals, and filter components such as chokes. The housing includes a base plate and four side plates vertically extending from edges of the base plate. The base plate and the four side plates define a space used to accommodate the filter components. Each of the terminals includes a fixing portion, an internal portion, and an external portion. The fixing portions are embedded in two opposite side plates of the housing. Each of the internal portions extends from one end of corresponding one of the fixing portions, and the internal portions are used to be soldered to leading wires of the filter components. Each of the external portions extends from the other end of corresponding one of the fixing portions, and the external portions are used to be soldered to solder pads of a circuit board whereby the filter is mounted on the circuit board by using the through-hole technology or the surface-mount technology.

The internal portions of the terminals of the conventional filter are short rod shaped, and therefore the leading wires of the filter components need to be manually wound around the internal portions. Furthermore, since pitches of the terminals are usually very short, the difficulty of dip soldering increases; for example, it is more likely to cause bridging between adjacent internal portions, resulting in a short circuit occurred between adjacent leading wires. The external portions of the terminals of the conventional filter are also short rod shaped, resulting that the external portions are easily skewed due to, for example, collision, and not well mounted on the circuit board. The conventional filter may further include a cover plate used to assemble with the housing to cover and protect the filter components disposed in the housing. The cover plate is usually fixed to the housing by using adhesive; however, it is likely to cause adhesive residue which affects the appearance of the filter and increases the complexity of the process.

### SUMMARY OF THE INVENTION

The present invention is adapted to providing a circuit board, a housing of an electrical component, and a filter, which may avoid or reduce manual soldering, bridging between adjacent internal portions, skew of external portions, and adhesive residue on the appearance.

According to an aspect of the present invention, there is provided a circuit board. The circuit board includes an upper surface, a lower surface opposite to the upper surface, and at least one side surface connected between the upper surface and the lower surface. The at least one side surface includes grooves formed therein. The grooves extend through the upper surface and the lower surface. The circuit board further includes upper solder pads, lower solder pads, and conductive connections. The upper solder pads are disposed flat against the upper surface and separately located beside the grooves. The lower solder pads are disposed flat against the lower surface and separately located beside the grooves. The conductive connections are separately disposed in the grooves, and the conductive connections provide guide grooves within the grooves. Two ends of each of the conductive connections are separately connected to corresponding one of the upper solder pads and corresponding one of the lower solder pads.

According to another aspect of the present invention, there is provided a housing of an electrical component. The housing includes the aforementioned circuit board, and a cover plate. The cover plate is parallel fixed to the upper surface of the circuit board through a fixing structure.

According to another aspect of the present invention, there is provided a filter. The filter includes the aforementioned circuit board, and at least one filter component. The at least one filter component is mounted on the upper surface of the circuit board.

According to another aspect of the present invention, there is provided a filter. The filter includes the aforementioned housing, and at least one filter component. The at least one filter component is mounted on the upper surface of the circuit board.

It is to be understood that both the foregoing general description and the following detailed description are by examples, and are intended to provide further explanation of the invention as claimed.

### BRIEF DESCRIPTION OF THE DRAWINGS

FIG. 1 is a schematic diagram illustrating a top perspective view of a circuit board according to an embodiment of the present invention;

FIG. 2 is a schematic diagram illustrating a bottom perspective view of the circuit board as shown in FIG. 1;

FIG. 3 is a schematic diagram illustrating an exploded perspective view of a housing of an electrical component according to an embodiment of the present invention;

FIG. 4 is a schematic diagram illustrating an exploded perspective view of a housing of an electrical component according to another embodiment of the present invention;

FIG. 5 is a schematic diagram illustrating an assembled perspective view of a filter according to an embodiment of the present invention;

FIG. 6 is a schematic diagram illustrating an exploded perspective view of the filter as shown in FIG. 5;

FIG. 7 is a schematic diagram illustrating a top view of various arrangements of filter components mounted on the circuit board; and

FIG. 8 to FIG. 12 are schematic diagrams illustrating top views of filters according to other embodiments of the present invention.

### DESCRIPTION OF THE PREFERRED EMBODIMENTS

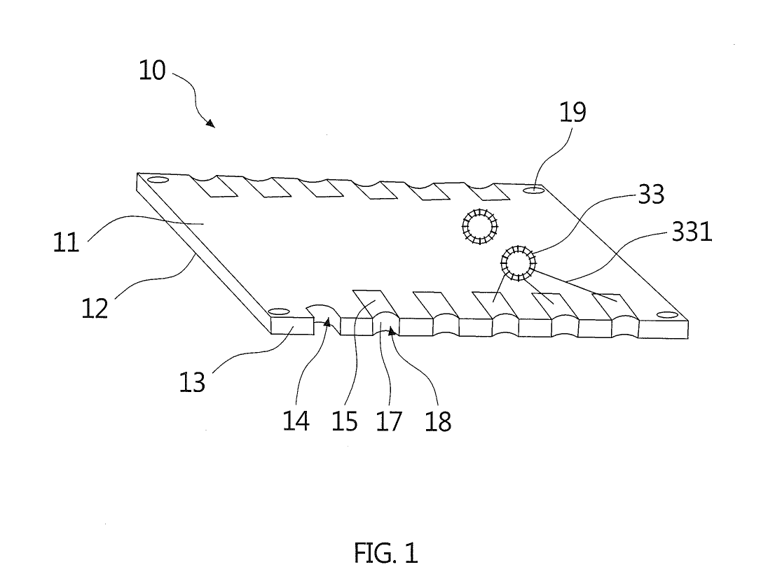

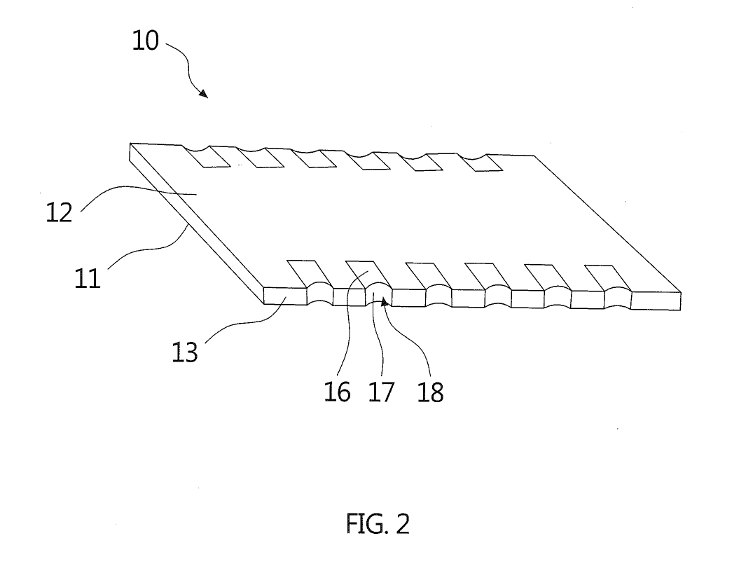

Referring to FIG. 1 and FIG. 2, there are provided schematic diagrams illustrating a top perspective view and a bottom perspective view of a circuit board 10 according to an embodiment of the present invention, respectively. The circuit board 10 is a rectangular board including an upper surface 11, a lower surface 12 opposite to the upper surface 11, and four side surfaces 13 connected between the upper surface 11 and the lower surface 12. Each of two opposite side surfaces 13 of the four side surfaces 13 includes grooves 14 formed therein. As shown in FIG. 1, for illustrative purpose, one of the grooves 14 in the far left position in the front of the circuit board 10 can be fully seen while omitting a conductive connection 17 disposed therein. The grooves 14 extend through the upper surface 11 and the lower surface 12. In other words, the grooves 14 are through, meaning that they pass all the way through the corresponding side surfaces 13 and their ends are open at the upper surface 11 and the lower surface 12.

The circuit board 10 further includes upper solder pads 15, lower solder pads 16, and conductive connections 17. The upper solder pads 15 are disposed flat against the upper surface 11 and are separately located beside the grooves 14. The lower solder pads 16 are disposed flat against the lower surface 12 and are separately located beside the grooves 14. The conductive connections 17 are separately disposed in the grooves 14 and provide guide grooves 18 within the grooves 14. Two ends of each of the conductive connections 17 are separately connected to corresponding one of the upper solder pads 15 and corresponding one of the lower solder pads 16. Practically speaking, each of the conductive connections 17, the corresponding one of the upper solder pads 15, and the corresponding one of the lower solder pads 16 compose a terminal.

Compared with the short rod-shaped internal portions of the terminals in the prior art, the upper solder pads 15 of the terminals in the present invention are thin, flat metal plates disposed flat against the upper surface 11. As shown in FIG. 1, filter components such as chokes 33 may be mounted on the circuit board 10, and then leading wires 331 of the chokes 33 are pulled across the upper solder pads 15 and positioned by the guide grooves 18. Therefore, leading wires of filter components may be soldered to the upper solder pads 15 by using automation technology rather than being manually wound around the internal portions and being soldered by dip soldering. It may avoid manual soldering and bridging between adjacent internal portions in the prior art, and therefore may reduce labor cost and increase production speed and yield.

Compared with the short rod-shaped external portions of the terminals in the prior art, the lower solder pads 16 of the terminals in the present invention are thin, flat metal plates disposed flat against the lower surface 12. Therefore, the lower solder pads 16 is impossible to skew, and may be well mount on the circuit board by using surface mount technology. It also may reduce labor cost and increase production speed and yield.

It should be noted that the embodiment as shown in FIG. 1 and FIG. 2 is not limited to the present invention. For example, the circuit board may be any shaped board such as a hexagonal board including an upper surface, a lower surface opposite to the upper surface, and six side surfaces connected between the upper surface and the lower surface. For example, the grooves may be only formed in one of the side surfaces.

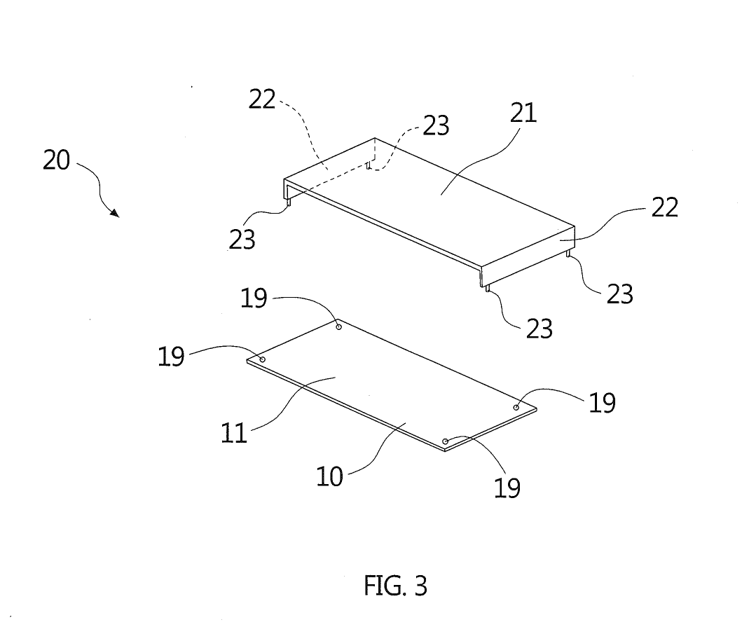

Referring to FIG. 3, there is provided a schematic diagram illustrating an exploded perspective view of a housing 20 of an electrical component according to an embodiment of the present invention. The housing 20 includes the circuit board 10 as shown in FIG. 1 and FIG. 2, and a cover plate 21. The cover plate 21 is parallel fixed to the upper surface 11 of the circuit board 10 through a fixing structure. In the embodiment, the fixing structure includes two side plates 22, four post-shaped fixing protrusions 23, and four fixing holes 19 corresponding to the four fixing protrusions 23. The two side plates 22 vertically extend from two opposite edges of the cover plate 21. Two of the four fixing protrusions 23 vertically extend from two ends of one of the two side plates 22, and the other two of the four fixing protrusions 23 vertically extend from two ends of the other one of the two side plates 22. The four fixing holes 19 are formed in the upper surface 11 of the circuit board 10. Therefore, the cover plate 21 is fixed to the circuit board 10 by the four fixing protrusions 23 placed into the four fixing holes 19.

In another embodiment, the fixing structure includes two side plates 22, three post-shaped fixing protrusions 23, and three fixing holes 19 corresponding to the three fixing protrusions 23. The two side plates 22 vertically extend from two opposite edges of the cover plate 21. Two of the three fixing protrusions 23 vertically extend from two ends of one of the two side plates 22, and the other one of the three fixing protrusions 23 vertically extends from one end of the other one of the two side plates 22. The three fixing holes 19 are formed in the upper surface 11 of the circuit board 10. Therefore, the cover plate 21 is fixed to the circuit board 10 by the three fixing protrusions 23 placed into the three fixing holes 19. The three fixing protrusions 23 and the three fixing holes 19 compose a mistake-proofing structure which may help the cover plate 21 and the circuit board 10 to assemble to each other without mistakes.

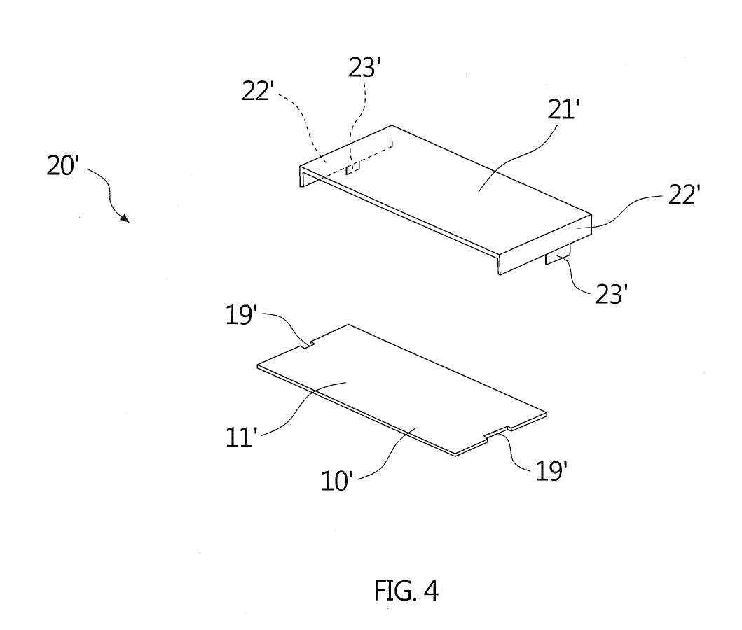

Referring to FIG. 4, there is provided a schematic diagram illustrating an exploded perspective view of a housing 20′ of an electrical is component according to another embodiment of the present invention. The housing 20′ includes the circuit board 10′ and a cover plate 21′. The cover plate 21′ is parallel fixed to the upper surface 11′ of the circuit board 10′ through a fixing structure. In the embodiment, the fixing structure includes two side plates 22′, two sheet-shaped fixing protrusions 23′, and two fixing holes 19′ corresponding to the two fixing protrusions 23′. The two side plates 22′ vertically extend from two opposite edges of the cover plate 21′. One of the two fixing protrusions 23′ vertically extends from a center of one of the two side plates 22′, and the other one of the two fixing protrusions 23′ vertically extends from a center of the other one of the two side plates 22′. The two fixing holes 19′ are formed in two opposite edges of the upper surface 11′ of the circuit board 10′. Therefore, the cover plate 21′ is fixed to the circuit board 10′ by the two fixing protrusions 23′ placed into the two fixing holes 19′.

In the embodiment, the two fixing protrusions 23′ are of different sizes, and correspondingly the two fixing holes 19′ are of different sizes. The two different-size fixing protrusions 23′ and the two different-size fixing holes 19′ compose another mistake-proofing structure which may help the cover plate 21′ and the circuit board 10′ to assemble to each other without mistakes.

Compared with the housing in the prior art, the housing in the present invention, for example the housing 20 or 20′, uses less material so as to reduce material cost. Moreover, the housing and the cover plate in the present invention, for example the housing 20 or 20′ and the cover plate 21 or 21′, are assembled to each other without using adhesive, and therefore it may avoid adhesive residue on the appearance.

It should be noted that the embodiments as shown in FIG. 3 and FIG. 4 are not limited to the present invention. For example, the fixing structure may include only one side plates vertically extending from the center or one edge of the cover plate. Moreover, the fixing structure may further include only one fixing protrusion vertically extending from the center of each side plate, and correspondingly one or more fixing holes are formed in the upper surface of the circuit board.

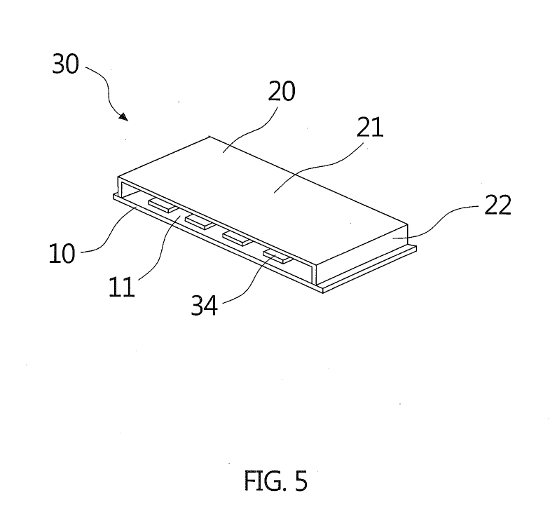

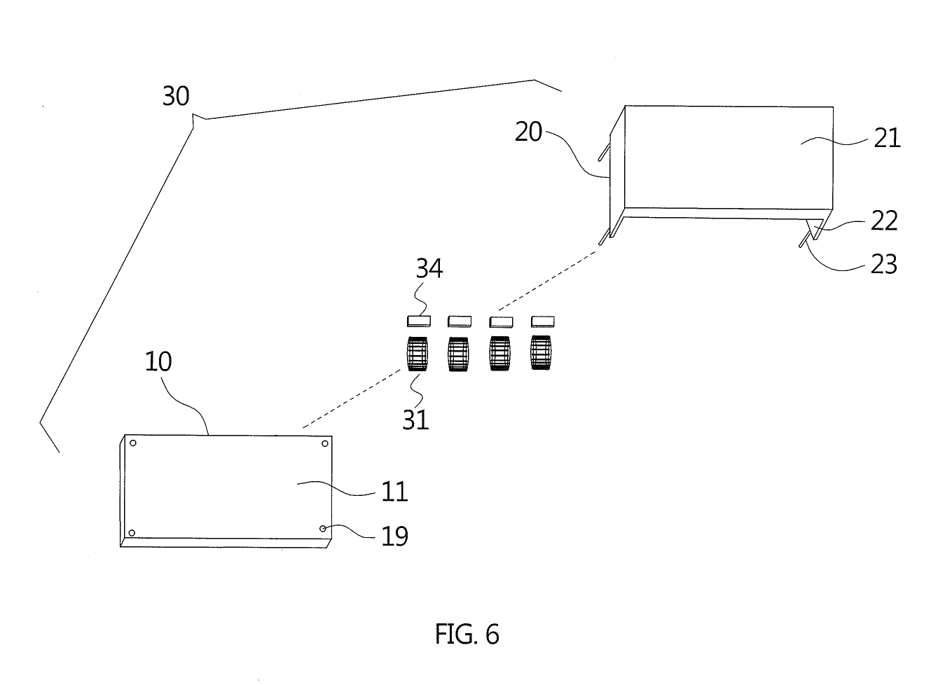

Referring to FIG. 5 and FIG. 6, there are provided schematic diagrams illustrating an assembled perspective view and an exploded perspective view of a filter 30 according to an embodiment of the present invention. The filter 30 includes the housing 20 as shown in FIG. 3, and filter components 31 and 34 mounted on the upper surface 11 of the circuit board 10. For simple purpose, FIG. 5 and FIG. 6 omit the upper solder pads 15, the lower solder pads 16, and the conductive connections 17. The filter component may be a choke or a transformer. The choke may consist of a coil of insulated wire wound on a rod-shaped magnetic core or a toroidal or doughnut-shaped magnetic core. In addition, the choke may consist of two coil of insulated wires wound on a toroidal or doughnut-shaped magnetic core, typically called a common mode choke. The transformer may be a network transformer such as a local area network (LAN) transformer.

It should be noted that the embodiment as shown in FIG. 5 and FIG. 6 is not limited to the present invention. For example, the filter may include the housing 20′ as shown in FIG. 4 rather than the housing 20 as shown in FIG. 3. For example, the filter may include the circuit board 10 as shown in FIG. 1 and FIG. 2, and filter components mounted on the upper surface 11 of the circuit board 10; in other words, the filter does not include the cover plate 21 and the fixing structure (including the side plates 22, the fixing protrusions 23, and the fixing holes 19).

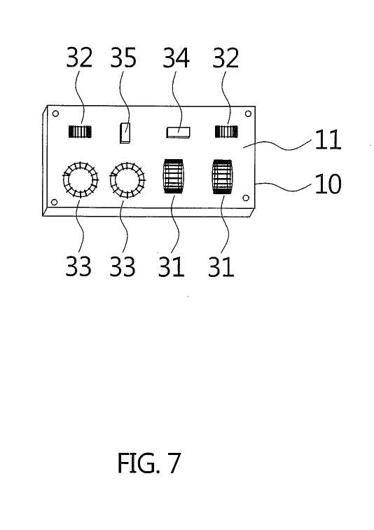

Referring to FIG. 7, there is provided a schematic diagram illustrating a top view of various arrangements of filter components 31 to 35 mounted on the upper surface 11 of the circuit board 10. For simple purpose, FIG. 7 omits the upper solder pads 15, the lower solder pads 16, and the conductive connections 17. The filter component may be a rod-shaped or toroidal filter component having an axis, or a rectangular cuboid filter component having a length. The filter component 31 is a toroidal filter component having an axis parallel to a longer edge of the upper surface 11. The filter component 32 is a toroidal filter component having an axis parallel to a shorter edge of the upper surface 11. The filter component 33 is a toroidal filter component having an axis perpendicular to the upper surface 11. The filter component 34 is a rectangular cuboid filter component having a length parallel to a longer edge of the upper surface 11. The filter component 35 is a rectangular cuboid filter component having a length parallel to a shorter edge of the upper surface 11.

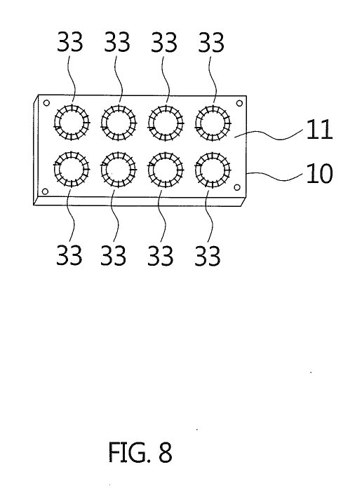

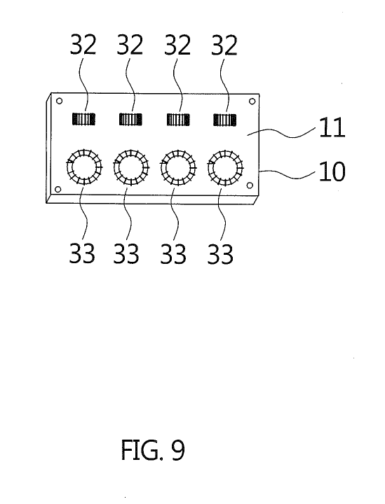

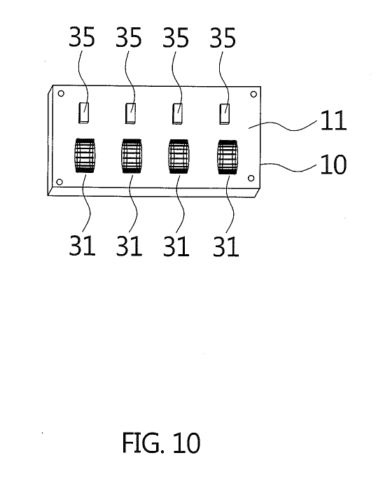

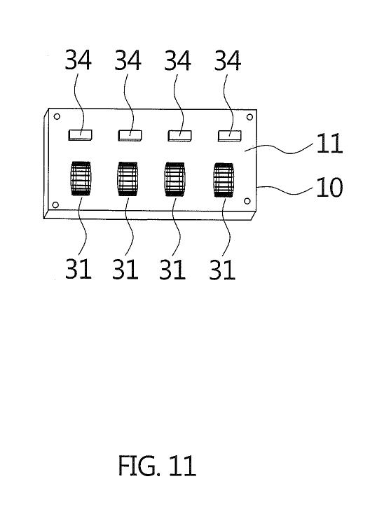

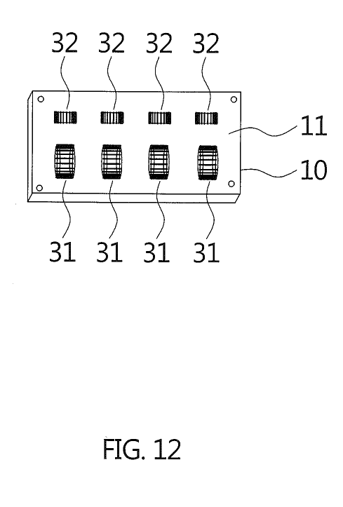

Referring to FIG. 8 to FIG. 12, there are provided schematic diagrams illustrating top views of filters according to other embodiments of the present invention. Each of the filters includes the circuit board 10 as shown in FIG. 1 and FIG. 2, and filter components mounted on the upper surface 11 of the circuit board 10. For simple purpose, FIG. 8 to FIG. 12 omit the upper solder pads 15, the lower solder pads 16, and the conductive connections 17. The filter components as shown in FIG. 8 are eight toroidal filter components 33. The filter components as shown in FIG. 9 are four toroidal filter components 32 and four toroidal filter components 33. The filter components as shown in FIG. 10 are four toroidal filter components 31 and four rectangular cuboid filter components 35. The filter components as shown in FIG. 11 are four toroidal filter components 31 and four rectangular cuboid filter components 34. The filter components as shown in FIG. 12 are four toroidal filter components 31 and four toroidal filter components 32.

It will be apparent to those skilled in the art that various modifications and variations can be made to the structure of the present invention without departing from the scope or spirit of the present invention. In view of the foregoing, it is intended that the present invention cover modifications and variations of this invention provided they fall within the scope of the following claims and their equivalents.

What is claimed is:

1. A circuit board comprising:
an upper surface;
a lower surface opposite to the upper surface;
at least one side surface connected between the upper surface and the lower surface, the at least one side surface comprising a plurality of grooves formed therein, the plurality of grooves extending through the upper surface and the lower surface;
a plurality of upper solder pads disposed flat against the upper surface and separately located beside the plurality of grooves;
a plurality of lower solder pads disposed flat against the lower surface and separately located beside the plurality of grooves; and
a plurality of conductive connections separately disposed in the plurality of grooves, the plurality of conductive connections providing a plurality of guide grooves within the plurality of grooves, two ends of each of the plurality of conductive connections separately connected to corresponding one of the plurality of upper solder pads and corresponding one of the plurality of lower solder pads.

2. A housing of an electrical component, the housing comprising:
the circuit board of claim 1; and
a cover plate parallel fixed to the upper surface of the circuit board through a fixing structure.

3. The housing of claim 2, wherein the fixing structure comprises at least one side plate vertically extending from at least one edge of the cover plate, whereby the cover plate is fixed to the circuit board by the at least one side plate connected to the circuit board.

4. The housing of claim 3, wherein the fixing structure further comprises:
at least one fixing protrusion vertically extending from the at least one side plate; and
at least one fixing hole corresponding to the at least one fixing protrusion, the at least one fixing hole formed in the upper surface of the circuit board,
whereby the cover plate is fixed to the circuit board by the at least one fixing protrusion placed into the at least one fixing hole.

5. The housing of claim 4, wherein the at least one fixing protrusion is post shaped.

6. The housing of claim 5, wherein the number of the at least one side plate is two, the two side plates vertically extending from two opposite edges of the cover plate; wherein the number of the at least one fixing protrusion is four, two of the four fixing protrusions vertically extending from two ends of one of the two side plates, the other two of the four fixing protrusions vertically extending from two ends of the other one of the two side plates; and wherein the number of the at least one fixing hole is four, the four fixing holes formed in the upper surface of the circuit board according to positions of the four fixing protrusions.

7. The housing of claim 5, wherein the number of the at least one side plate is two, the two side plates vertically extending from two opposite edges of the cover plate; wherein the number of the at least one fixing protrusion is three, two of the three fixing protrusions vertically extending from two ends of one of the two side plates, the other one of the three fixing protrusions vertically extending from one end of the other one of the two side plates; and wherein the number of the at least one fixing hole is three, the three fixing holes formed in the upper surface of the circuit board according to positions of the three fixing protrusions.

8. The housing of claim 4, wherein the at least one fixing protrusion is sheet shaped.

9. The housing of claim 8, wherein the number of the at least one side plate is two, the two side plates vertically extending from two opposite edges of the cover plate; wherein the number of the at least one fixing protrusion is two, each of the two fixing protrusions vertically extending from a center of corresponding one of the two side plates; and wherein the number of the at least one fixing hole is two, the two fixing holes formed in two opposite edges of the upper surface of the circuit board according to positions of the two fixing protrusions.

10. The housing of claim 9, wherein the two fixing protrusions are of different sizes.

11. A filter comprising:
the circuit board of claim 1; and
at least one filter component mounted on the upper surface of the circuit board.

12. The filter of claim 11, wherein the at least one filter component comprises a choke or a transformer.

13. The filter of claim 11, wherein the at least one filter component comprises a rod-shaped or toroidal filter component having an axis, or a rectangular cuboid filter component having a length.

14. The filter of claim 13, wherein the axis is parallel to a longer edge of the upper surface, or is parallel to a shorter edge of the upper surface, or is perpendicular to the upper surface; or wherein the length is parallel to a longer edge of the upper surface, or is parallel to a shorter edge of the upper surface.

15. A filter comprising:
the housing of claim 2; and
at least one filter component mounted on the upper surface of the circuit board.

16. The filter of claim 15, wherein the at least one filter component comprises a choke or a transformer.

17. The filter of claim 15, wherein the at least one filter component comprises a rod-shaped or toroidal filter component having an axis, or a rectangular cuboid filter component having a length.

18. The filter of claim 17, wherein the axis is parallel to a longer edge of the upper surface, or is parallel to a shorter edge of the upper surface, or is perpendicular to the upper surface; or wherein the length is parallel to a longer edge of the upper surface, or is parallel to a shorter edge of the upper surface.
